(19) United States
(12) Patent Application Publication
(10) Pub. No.: US 2026/0145578 A1
(43) Pub. Date: May 28, 2026

(54) POWER BATTERY HEALTH PREDICTION AND EVALUATION SYSTEM FOR ELECTRIC VEHICLES, ENERGY STORAGE SYSTEM AND UNINTERRUPTIBLE POWER SUPPLIES AND CHARGER WITH THE SYSTEM

(71) Applicant: ATURS DESIGN CO., LTD., Taipei City (TW)

(72) Inventors: CHUN-PENG KUO, Taipei City (TW); CHUN-YI SU, Taipei City (TW)

(21) Appl. No.: 19/031,127

(22) Filed: Jan. 17, 2025

(30) Foreign Application Priority Data
Nov. 26, 2024 (TW) 113145618

(51) Int. Cl. B60L 58/16; B60R 16/023; G01R 31/367; G01R 31/3842; G01R 31/389; G01R 31/392; G05B 13/02; G07C 5/00; G07C 5/08; G07C 5/10; H01M 10/48; H02J 9/06

(52) U.S. Cl. CPC B60L 58/16; B60R 16/0231; G01R 31/367; G01R 31/3842; G01R 31/389; G01R 31/392; G05B 13/027; G07C 5/008; G07C 5/085; G07C 5/10; H01M 10/482; H01M 2220/20; H02J 9/06

(57) ABSTRACT

A system for predicting and evaluating the health level of power batteries for electric vehicles, energy storage system and uninterruptible power supplies comprises a database unit, a reading unit and an artificial intelligence (AI) processing unit, which can directly predict and evaluate the health level of power batteries for electric vehicles, energy storage system or uninterruptible power supplies, or be integrated into a charger. The database unit is connected with batteries of electric vehicles, energy storage system or uninterruptible power supplies through a protocol signal device to store various electrical characteristics of batteries of different brands and tested batteries. The reading unit cooperates with the database unit, and the AI processing unit realizes deep learning, induction, summarization and repetition training, so as to predict the life span of the battery under test according to the optimal AI model, provide battery health state prediction and ensure reliable charging effect.

### BACKGROUND OF THE INVENTION

### Field of the Invention

The present invention relates to a battery health prediction and evaluation system, and more particularly to a battery health prediction and evaluation system which can directly predict the battery health state for electric vehicles, energy storage system and uninterruptible power supplies, or be equipped with a charger to provide the battery health state prediction for the electric vehicles, energy storage system and uninterruptible power supplies.

### Description of Related Art

Electric vehicles (e.g., electric motorcycles or electric cars) is not only the focus in the development of the transportation field in modern days, but also is one of the global development projects after the oil crisis. With the mature development of electric vehicles, batteries and chargers used to provide electric vehicle power are also crucial development projects, that is, electric vehicles and chargers are designed to complement each other. In addition to the batteries, the electric vehicles also relies on the charging piles to supply power to maintain stability, in order to construct a complete transportation system for industrial utilization and improve resource utilization.

As known, the battery power consumption of electric vehicles must be supplemented by chargers to maintain sufficient power for driving, so that convenient and reliable charging field setting will contribute to the overall development and convenience of use of electric vehicles. The health indicators of the battery include, for example, the state-of-health (SOH), state of charge (SoC), state of energy (SoE) and state of safety (SoS), etc. Should inaccurate health states occurs, it may cause the actual battery capacity to be much lower than expected, which will lead to accidental over discharging. Some studies have shown that in the process of charging electric vehicles, the reliability of chargers can be worsen if constantly charging batteries under improper use or old batteries. Furthermore, for the battery with unknown remaining life span, it is likely that users replace the battery way before the end of its life span, thus increasing the cost of the battery replacement.

Therefore, if the information related to prediction of battery health and remaining life span can be provided precisely and timely, the battery under test can be replaced in time, the electric vehicle can travel with peace of mind, and the charger can be directly protected in a substantial manner, thereby providing a reliable charging effect of the charger.

Furthermore, the batteries in the energy storage system and uninterruptible power supply are also a kind of spare or emergency equipment for users. Therefore, it is also an important topic to be aware of the remaining life span of the battery in advance to ensure the normal operation thereof.

### BRIEF SUMMARY OF THE INVENTION

An objective of the present invention is to provide a power battery health prediction and evaluation system for electric vehicles, energy storage system and uninterruptible power supplies, which can predict the health state of the batteries of the electric vehicles, energy storage system and uninterruptible power supplies when the electric vehicles are charged or connected to the energy storage system and uninterruptible power supplies, so as to provide information on timely replacement of the tested batteries, so that the electric vehicles, energy storage system and uninterruptible power supplies can be prevented from the worries whether the batteries are dead or not, and thus can substantially provide a reliable charging effect.

Another objective of the present invention is to predict and evaluate the health level of power batteries for electric vehicles, energy storage system and uninterruptible power supplies. The system is integrated into a charger, and after the charging of the electric vehicles is completed, the battery life-related information of the electric vehicles can be predicted at the same time, so that users can replace the batteries in proper time to avoid prematurely replacing the batteries, in order to provide direct protection for chargers.

In order to achieve the above objectives, the present invention provides a power battery health prediction and evaluation system for an electric vehicle, energy storage system and uninterruptible power supply, which comprises: a database unit, a reading unit connected with the database unit, and an artificial intelligence (AI) processing unit.

The database unit is connected with batteries of the electric vehicle, the energy storage system and the uninterruptible power supply through a protocol signal device, and stores data of various electrical characteristics of batteries of different brands and tested batteries to establish a database. The database unit includes: a memory that stores at least the electrical characteristics of batteries of different brands, such as charging, discharging, and impedance-related data, as well as the battery internal resistance, battery voltage, and battery current of the tested battery, as well as the artificial The AI model established by the intelligent (AI) processing unit; a measurement interface is connected to the memory, programmed in LabVIEW and paired with a Data Acquisition System (DAQ) and connected to an external circuit to measure the battery voltage. Then use the voltage difference measured by the battery to calculate the internal resistance of the battery, and store the relevant test data in the memory.

The data of various electrical characteristics of the battery under test measured through the measurement interface are established into a database.

The reading unit comprises: a microcontroller; and a voltage-current sensor and a local area network controller connected with the microcontroller, wherein the microcontroller is arranged to manage various associated data of batteries, calculate various obtained parameters of the batteries including at least one of a voltage, current and temperature as physical data, and convert the physical data into digital data; the voltage-current sensor reads values comprising voltages and currents from the battery under test and transmits the values to the microcontroller; the LAN controller is used for transmitting state data of the battery under test processed by the microcontroller to the AI processing unit. The AI processing unit is arranged to refer to data associated with electrical characteristics of different brands of batteries in the database unit as historical data, and refer to state data of the battery under test of the electric vehicle obtained by the reading unit as substantive data, to perform deep learning, induction, summarization and repetition training, so as to perform calculation based on an optimal AI model to predict health state and life span of the battery under test.

Through the cooperative operation of the database unit and the reading unit, the state data of the battery under test can be obtained from the batteries of the electric vehicle, the energy storage system and the uninterruptible power supply when the electric vehicle is charged or connected to the energy storage system and the uninterruptible power supply, and the health state can be predicted.

The AI processing unit conducts deep learning, induction, summarization and repetition training according to the electrical characteristics of different brands of batteries in the database unit, such as charging, discharging and impedance-associated data (historical data), and the state data (substantive data) of the battery under test of the electric vehicle obtained by the reading unit, so as to generate different AI models, and perform calculation according to the optimal of the different AI models to predict the life span of the battery under test.

### BRIEF DESCRIPTION OF THE DRAWINGS

In order to allow the abovementioned and other purposes, features, advantages and embodiments of the present disclosure to be more clearly understood, the accompanying drawings are described as following:

FIG. 1 is a diagram showing the conceptual application of a power battery health prediction and evaluation system for electric vehicles, energy storage system and uninterruptible power supplies.

FIG. 2 is a diagram showing a measurement interface of the power battery health prediction and evaluation system for electric vehicles, energy storage system and uninterruptible power supplies, which is written in LabVIEW programming.

FIG. 3 is an electrical data diagram of the battery under test displayed by the measurement interface of the power battery health prediction and evaluation system for electric vehicles, energy storage system and uninterruptible power supplies according to the present invention through the test circuit of the.

FIG. 4 and FIG. 5 are schematic diagrams showing the system for predicting and evaluating the health level of the power battery for electric vehicles, energy storage system and uninterruptible power supplies is integrated into a charger, in which a database unit, a reading unit and an AI processing unit cooperate with each other.

FIG. 6-8 are architectural diagrams of three AI training methods adopted by the AI processing unit of the power battery health prediction and evaluation system for electric vehicles, energy storage system and uninterruptible power supplies.

FIG. 9 is a schematic diagram of the AI processing unit of the power battery health prediction and evaluation system for electric vehicles, energy storage system and uninterruptible power supplies, which trains, predicts and analyzes the tested batteries.

### DETAILED DESCRIPTION OF THE INVENTION

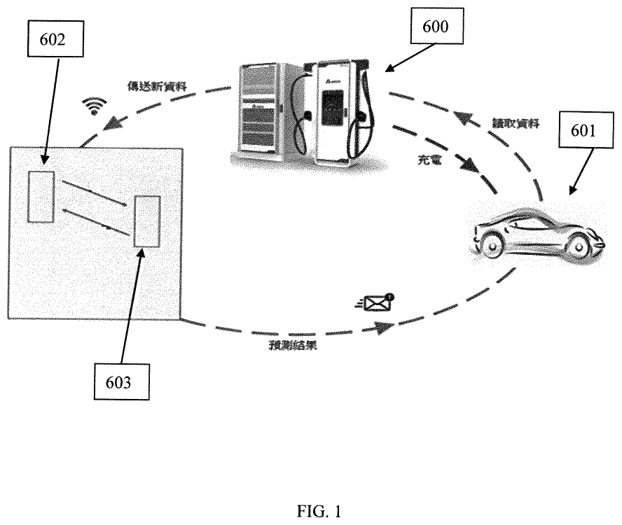

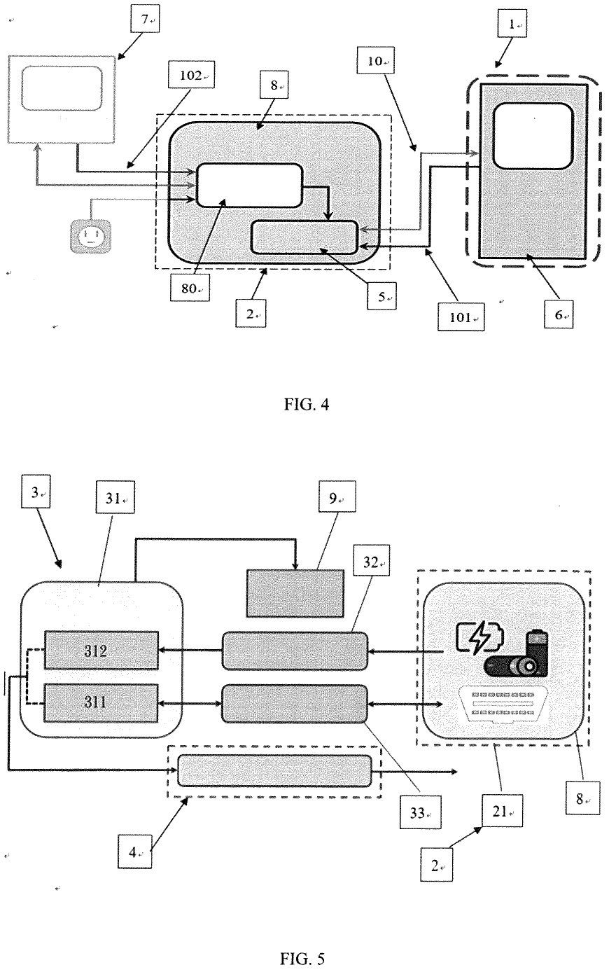

As the application concept of the power battery health prediction and evaluation system of the present invention is the same when applied to electric vehicles, energy storage system and uninterruptible power supplies, the following only illustrates the electric vehicles in details. Please refer to FIG. 1 which is a diagram showing the conceptual application of a power battery health prediction and evaluation system. As shown in FIG. 1, the power battery health prediction and evaluation system of the present invention can be installed in the background to directly predict and evaluate the power battery health level of electric vehicles, or integrated into a charger (shown in FIGS. 4-5). When charging, the battery health state of electric vehicles can be predicted at the same time. That is, through the power battery health prediction and evaluation system of the present invention, when the charger 600 charges the electric vehicle 601, the battery under test of the electric vehicle 601 will be measured to obtain the data of various electrical characteristics as the database 602, and then the data of various electrical characteristics of the actual battery under test will be read (as shown in the read data in FIGS. 1 and T1 in FIG. 9). With the artificial intelligence (AI) 603 performing deep learning, induction, summarization and repetition training are conducted, as well as the optimal AI model (as shown in T2 of FIG. 9) predicting the battery health level of the battery under test, after the charging is completed, the information can be provided to the charging user (e.g., a customer) of the electric vehicle 601 through the charging receipt or a handheld device. The information may comprise data related to the charging fee and battery health (as shown in the prediction result of FIG. 1), so as to provide the charging user (e.g., the customer) with timely battery replacement.

Referring to FIGS. 4 and 5, the system for predicting and evaluating the health level of the power battery of an electric vehicle of the present invention is integrated into a charger. As shown in FIG. 5, the system 1 comprises a database unit 2, a reading unit 3 and an AI processing unit 4 connected with the database unit 2, wherein the database unit 2 is connected with the battery 5 and the DC charger 6 (or the AC charger 7) of the electric vehicle 8 through a protocol signal device 10 (shown in FIG. 4). The protocol signal device 10 is a protocol signal trace, which provides a communication protocol for three-way connection between the battery, the charger of the system and the electric vehicle, so as to store data of various electrical characteristics of batteries of different brands and batteries under test for establishment. When a user picks up the charger to charge the electric vehicle, the protocol signal trace (e.g. the protocol signal device 10) is connected with the on-board diagnosis system (OBD II) on the circuit board 80 of the electric vehicle 8, and the data of various electrical characteristics of the battery 5 of the electric vehicle 8 are synchronously read. In addition, the charger has a DC power trace 101 (or AC power trace 102) which can be used to connect with DC charger 6 or AC charger 7 respectively to provide the required amount of charging power.

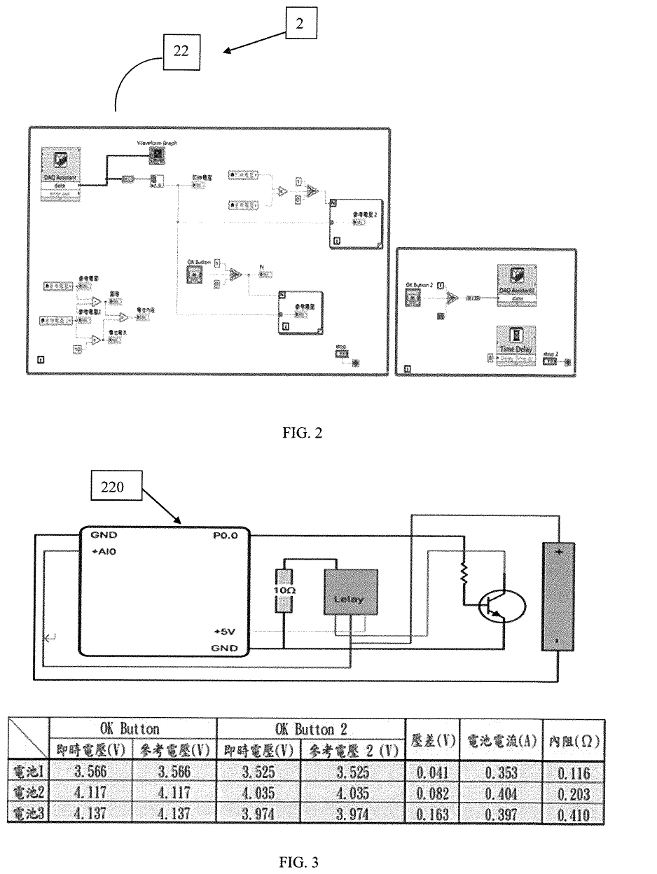

As shown in FIG. 5, the database unit 2 comprises a memory 21 and a measurement interface 22 (see FIG. 2). The memory 21 stores the electrical characteristics of the batteries of different brands, such as charging, discharging and impedance-associated data, as well as the battery internal-resistance, battery voltage and battery current of the battery under test, and the AI model established by the AI processing unit. The measurement interface 22 is connected with the memory 21, which is programmed with LabVIEW, equipped with a data acquisition system (DAQ), and connected with an external circuit to measure the battery voltage and further calculate the internal-resistance of the battery according to a measured voltage difference of the battery, and stores the tested associated data into the memory 21. That is, the measuring interface 22 measures the battery internal-resistance, battery voltage and battery current to obtain the various associated parameters, and the measured voltage value of the battery under test is taken as a first reference voltage. When the relay is switched to 10 ohms after several seconds, the voltage value of the battery under test is taken as a second reference voltage. The first reference voltage is subtracted by the second reference voltage to obtain a voltage difference value. The second reference value is divided by the load resistance to obtain a batter current value. The voltage difference is divided by the batter current value to obtain the battery internal-resistance value (please refer to the following illustrations for more details).

Please refer to FIG. 5. The reading unit 3 comprises a microcontroller 31, a Voltage-current sensor 32, and a local area network controller 33 connected with the microcontroller 31, wherein the microcontroller 31 is used for managing various associated data 311 of the battery, calculating various parameters 312 of the battery, such as voltage, current, temperature, etc., and converting these physical data into digital signals to be displayed on the screen 9. The voltage-current sensor 32 reads the values of voltage-current from the battery under test to the microcontroller 32. The LAN controller 33 is based on the bus standard (e.g., CAN bus) for vehicles to transmit the state data of the battery under test which is processed by the microcontroller 31 to the AI processing unit 4. The cooperative relationship between the reading unit 3 and the AI processing unit 4 can be clearly seen from FIG. 5.

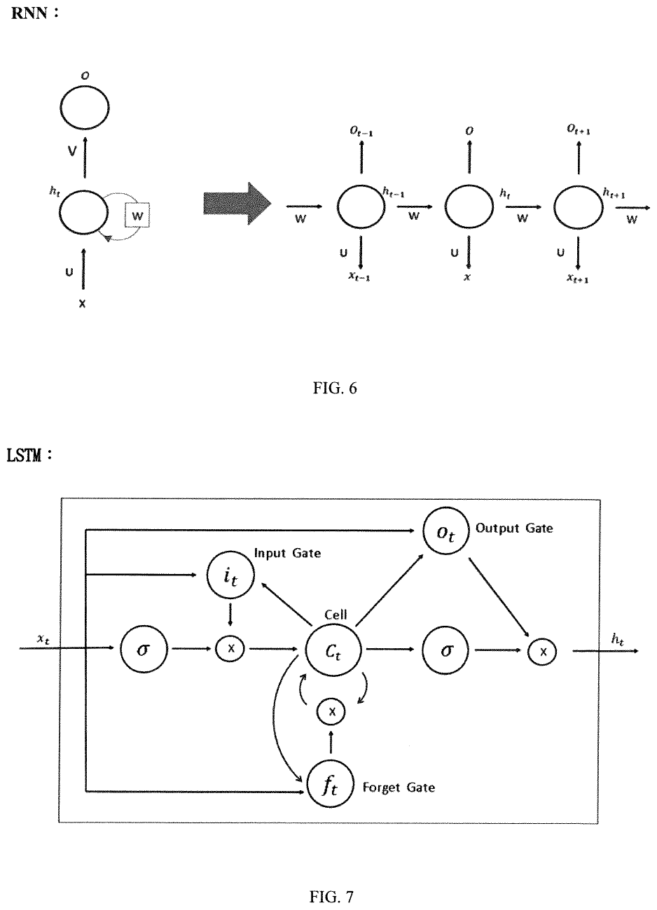

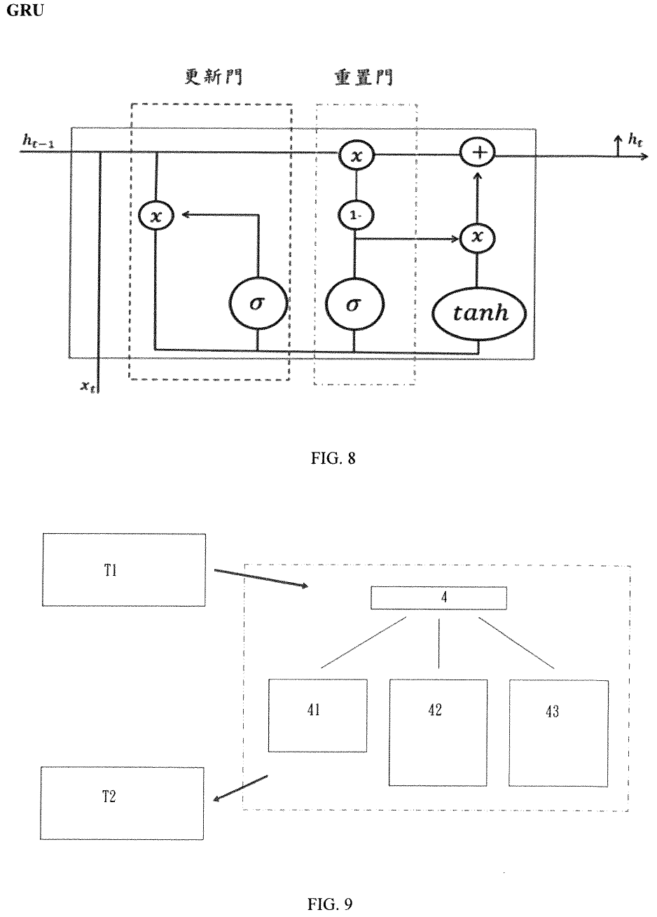

The AI processing unit 4 refers to the data related to the electrical characteristics of different brands of batteries in the database unit 2 as historical data, refers to the state data of the tested batteries of electric vehicles obtained by the reading unit 3 as substantive data to carries out deep learning, induction, summarization and repetition training (please refer to the following FIGS. 6-8 for more details), adopts a recursive neural network (RNN, as shown in FIG. 6), long-term and short-term memory model (LSTM, as shown in FIG. 7) or gating cycle unit (GRU as shown in FIG. 8), and further perform calculation according to the optimal AI model to predict the battery health and life of the battery under test.

The overall design of the present invention can be referred from FIG. 2 to FIG. 8. The measuring interface 22 of the present invention can provide simple and easy operation steps by programming the human-computer interface with LabVIEW (as shown in FIG. 2), which are as follows:
Step 1: Press the button “Ok Button” in the man-machine interface area to measure the instantaneous voltage value as the reference voltage;
   ↓
Step 2: At this moment, the reference voltage is the current battery voltage;
   ↓
Step 3: Press the button “Ok Button 2” in the man-machine interface area. At this time, the relay switches the circuit and measures the instantaneous voltage as the reference voltage 2;
   ↓
Step 4: Subtract the reference voltage from the reference voltage 2 to obtain a voltage difference;
   ↓
Step 5: Divide the reference voltage 2 by the load resistance to obtain the battery current;
   ↓
Step 6: Divide the voltage difference by the battery current to find the battery internal resistance.

Please further refer to FIG. 3. The measuring interface 22 measures the battery internal-resistance, battery voltage and battery current through the test circuit 220 (refer to FIG. 3), and obtains associated parameters. The following actual tests are conducted with three 18650 lithium-ion batteries. When the measuring interface 22 (man-machine interface) programmed by the Lab VIEW presses the button “Ok Button” according to the above Step 1, the battery voltage is measured, and the measured voltage values are displayed as a reference in the attached table in FIG. 3. Then the button “Ok Button 2” is pressed, and after several seconds, the relay switches to the load resistance of 1002 and displays the battery under test voltage in the field “reference voltage 2” (i.e., the second reference voltage) as shown in FIG. 3. The measurement results are shown in the attached table in FIG. 3. The voltage difference (V) can be obtained by subtracting the reference voltage (i.e., the first reference voltage) by the reference voltage 2 (i.e., the second reference voltage), while the battery current (A) is obtained by dividing the reference voltage 2 (the second reference voltage) by the upper load resistance, and finally the battery internal-resistance ((2) is obtained by dividing the voltage difference (V) by the battery current (A).

The cooperative relationship between the reading unit 3 and the AI processing unit 4 in the present invention are shown in FIG. 4 and FIG. 5. The AI processing unit 4 takes the data related to the electrical characteristics of different brands of batteries in the database unit 2 (FIG. 4) as historical data, and obtains the state data of the tested batteries of electric vehicles as substantive data according to the reading unit 3, so that the AI processing unit 4 can carry out deep learning, induction, summarization and repetition training. As shown in FIG. 9, the AI processing unit 4 carries out the model building 41, model training 42 and model prediction 43, and can perform calculation according to the optimal AI model to predict the battery health and life span of the battery under test. The construction of the optimal AI model may adopt the recursive neural network (RNN), long-term and short-term memory model (LSTM) or gated cycle unit (GRU), and the details thereof can be referred to FIGS. 6-8.

RNN model (as shown in FIG. 6): This model is trained to process and convert sequential data input into specific sequential data output. Sequential data refers to a kind of data whose sequence components are interrelated according to complex semantic and grammatical rules, such as single words, sentences or time series data. The related formulas of RNN architecture diagram in FIG. 6 are as follows:

$${h}_{t} = {σ}_{h} ( {i}_{t} ) = {σ}_{h} ( {U}_{h} {x}_{t} + {V}_{h} {h}_{t - 1} + {b}_{h} ) \qquad Formula 1$$

$${y}_{t} = {σ}_{y} ( {a}_{t} ) = {σ}_{y} ( {W}_{y} {h}_{t} + {b}_{h} ) \qquad Formula 2$$

where hₜ denotes the hidden layer at the time t′ Uₕxₜ denotes the linear transformation of the output vector xₜ at the current time t performed by the weighting matrix Uₕ, Vₕhₜ₋₁ denotes the linear transformation of the hidden state vector hₜ₋₁ at the previous time (t−1) performed by the weighting matrix Vₕ; bₕ denotes the bias term of the hidden state for adjusting the output; the activation function σₕ is usually tanh or ReLU, for introducing nonlinear transformation, and the effect thereof is to compress the output to between −1 to 1; yₜ denotes the output vector; W_{y}hₜ denotes the linear transformation of the hidden state hₜ performed by the weighting matrix W_{y}; the activation function σ_{y} is usually softmax or sigmoid based on the actual needs of the output layer.

LSTM model (see FIG. 7): LSTM and RNN have similar frameworks, but LSTM's internal structure is more complicated. LSTM introduces the cell vector Cₜ to solve the problem of gradient disappearance. The cell vector C can be regarded as another hidden layer but distinguished using a different term due to different design concept. It can be found in following Formula 4 that Cₜ is designed as the linear addition of Cₜ and Cₜ₋₁. The structural formula of LSTM in FIG. 8 is as follows:

Forgot gate: Allow the network to selectively forget irrelevant information. The forget gate controls the cell state hₜ₋₁ in the previous time step, where fₜ denotes the forget gate, W_{f} denotes the weighting matrix, b_{f} is a bias term, and σ denotes a sigmoid activation function.

$${f}_{t} = σ ( {W}_{f} * [ {h}_{t - 1} , {x}_{t} ] + {b}_{f} ) \qquad Formula 1$$

Input gate: Allow the network to selectively add new information to the cell state. The input gate determines how much new information will be added to the cell state. The candidate cell state \tilde{C}ₜ is a candidate value of the new information.

$${i}_{t} = σ ( {W}_{i} * [ {h}_{t - 1} , {x}_{t} ] + {b}_{1} ) \qquad Formula 2$$

$${\tilde{C}}_{t} = tanh ( {W}_{C} * [ {h}_{t - 1} , {x}_{t} ] + {b}_{C} ) \qquad Formula 3$$

Cell State: It is transmitted almost without modification between time steps, which enables LSTM to retain long-term information. The update of the cell state Cₜ combines the cell state Cₜ₋₁ of the previous time step with the current candidate cell state \tilde{C}ₜ.

$${C}_{t} = {f}_{t} * {C}_{t - 1} + {i}_{t} * {\tilde{C}}_{t} \qquad Formula 4$$

Output gate: Control the influence of the current cell state on the hidden state, thus determining the output of LSTM. The output gate controls how much information of the current cell state σₜ can affect the hidden state hₜ. The hidden state hₜ is the combination of the result of the output gate and the nonlinear transformation (through tanh function) of the current cell state.

$${o}_{t} = σ ( {W}_{o} * [ {h}_{t - 1} , {x}_{t} ] + {b}_{o} ) \qquad Formula 5$$

$${h}_{t} = {o}_{t} * tanh ( {C}_{t} ) \qquad Formula 6$$

GRU model (see FIG. 8): It can solve the problems of unable to have long-term memory and reverse propagation in gradient, which is similar to LSTM but relatively simple to train. There are two kinds of gates in GRU model (i.e., the reset gate and the update gate). Unlike LSTM, GRU has no single-cell state, but uses the hidden state for information storage and transmission. The GRU model architecture formula in FIG. 9 is as follows:

Reset gate: The reset gate determines how much information in the hidden state hₜ₋₁ of the previous time step needs to be reset.

$${r}_{t} = σ ( {W}_{r} + [ {h}_{t - 1} , {χ}_{t} ] ) \qquad Formula 1$$

Update gate: The update gate determines the mixture ratio of the hidden state hₜ₋₁ of the previous time step and the candidate hidden state of the current time step.

$${z}_{t} = σ ( {W}_{z} * [ {h}_{t - 1} , {χ}_{t} ] ) \qquad Formula 2$$

Candidate hidden state: The candidate hidden state is calculated via the hidden state hₜ₋₁ of the previous time step controlled by the reset gate and the input xₜ of the current time step.

$${\tilde{h}}_{t} = tanh ( W * [ {r}_{t} * {h}_{t - 1} , {x}_{t} ] ) \qquad Formula 3$$

Hidden State Update: The hidden state hₜ of the current time step is the weighted sum of the hidden state hₜ₋₁ of the previous time step and the candidate hidden state \tilde{h} according to the output zₜ of the update gate.

$${h}_{t} = ( 1 - {z}_{t} ) * {\tilde{h}}_{t} + {z}_{t} * {h}_{t - 1} \qquad Formula 4$$

Combining the above three methods to predict the health level of the battery under test is to forward propagate the obtained historical data and substantive data in a one by one manner, then introduce the obtained output result and the standard answer into the loss function to calculate the difference between the two, and then use a gradient descent-like optimizer to perform backward propagation to adjust the weight in teach sensor so, in order to train an optimal model under the premise of reducing the difference, thus providing accurate battery life prediction and health assessment.

The battery prediction can be further conducted using the commercially available 18650 lithium ion battery (lithium cobaltate) as follows. The experimental methods and recorded data of this use comprise the following: At room temperature, the battery is tested in three different operation modes (the charging mode, discharging mode and impedance measurement). The charging mode is conducted in constant current (CC) mode with a current of 1.5 A until the battery voltage reaches 4.2V, and then is continued in a constant voltage (CV) mode until the charging current is reduced to 20 mA. The discharging was conducted in a constant current (CC) mode with a current of 2 A until the battery voltage dropped to 2.7V (B0005), 2.5V (B0006), 2.2V (B0007) and 2.5V (B0018) respectively. The impedance measurement is conducted by electrochemical impedance spectroscopy (EIS) frequency scanning from 0.1 Hz to 5 kHz. Repeated charging and discharging cycles accelerate the aging of the battery, and impedance measurement provides the changes of internal parameters of the battery with the aging progress. The experiment stopped when the battery reaches the end-of-life (EOL) standard. This standard is that the rated capacity decreased by 30% (e.g., from 2 Ahr to 1.4 Ahr). This set of data can be used to predict the remaining power (for a given discharge cycle) and the remaining useful life (RUL); charging: battery terminal voltage, battery output current, voltage and current measured on the charger, battery temperature and cyclic time vector; discharging: battery terminal voltage, battery output current, battery temperature, voltage and current measured on the load, cyclic time vector and the battery capacity with voltage reduced to 2.7V. Impedance: the current in the sensing branch, the current in the battery branch, the ratio of the above two currents, the battery impedance calculated according to the original data, the calibrated and smoothed battery impedance, the estimated electrolyte resistance and the estimated charge transfer resistance. The battery data disclosed above is then applied to three models selected and trained in this invention, thereby obtaining the SOH prediction curves (charging, discharging and impedance) predicted by the following three models respectively.

The above three AI models are somehow related, although the data originates from the prediction made based on the public data set “NASA Prognostics Data Repository (2007) “Battery Data Set”” (Battery serial numbers: B0005-B0018, which are the 18650 lithium-ion (lithium cobaltate) battery available in the market), each of the different batteries or batteries of different brands may have its own characteristics, such that the battery condition of the electric vehicle can be predicted and evaluated through the power battery health prediction and evaluation system of the present invention.

To sum up, the electric vehicle adopting the system of the present invention, the health state of the battery of the electric vehicle can be predicted while charging, so as to timely provide the information regarding replacement of the battery under test, which can make user of the electric vehicle free from the concerns of not knowing whether the battery is out of electricity, substantially provide direct protection and reliable charging effect for the charger, and provide accurate and rapid information related to predicting the health state and remaining life span of the battery, so that the battery under test can be timely replaced and the user of the electric vehicle can drive with peace of mind.

The above-mentioned invention is applied to a system for predicting and evaluating the health level of the power battery of an electric vehicle. When the present invention is applied to an energy storage system or an uninterruptible power supply, the user only needs to use the above-mentioned protocol signal trace (e.g., the protocol signal device 10) to connect the energy storage system or the uninterruptible power supply to obtain the state data of the battery under test of the energy storage system or the uninterruptible power supply. Then, with the AI processing unit performing in-depth learning, induction, summarization and repetition training on the state data, as well as the predicting the optimal AI model, the life span of the energy storage system or the uninterruptible power supply can be predicted precisely.

What is claimed is:

1. A power battery health prediction and evaluation system for an electric vehicle, energy storage system and uninterruptible power supply, which comprises: a database unit, a reading unit connected with the database unit, and an artificial intelligence (AI) processing unit, wherein
the database unit is connected with batteries of the electric vehicle, the energy storage system and the uninterruptible power supply through a protocol signal device, and stores data of various electrical characteristics of batteries of different brands and tested batteries to establish a database;
the reading unit comprises: a microcontroller; and a voltage-current sensor and a local area network controller connected with the microcontroller, wherein the microcontroller is arranged to manage various associated data of batteries, calculate various obtained parameters of the batteries including at least one of a voltage, current and temperature as physical data, and convert the physical data into digital data; the voltage-current sensor reads values comprising voltages and currents from the battery under test and transmits the values to the microcontroller; the LAN controller is used for transmitting state data of the battery under test processed by the microcontroller to the AI processing unit;
the AI processing unit is arranged to refer to data associated with electrical characteristics of different brands of batteries in the database unit as historical data, and refer to state data of the battery under test of the electric vehicle obtained by the reading unit as substantive data, to perform deep learning, induction, summarization and repetition training, so as to perform calculation based on an optimal AI model to predict health state and life span of the battery under test.

2. The power battery health prediction and evaluation system according to claim 1, wherein the protocol signal device is a protocol signal trace, which provides a communication protocol for connection between the system and the power batteries of the electric vehicles, energy storage system or uninterruptible power supply, and the protocol signal trace is connected with an on-board diagnosis system (OBD II) on the electric vehicles, energy storage system or uninterruptible power supply, so as to synchronously read data of various electric characteristics of the power batteries of the electric vehicles, energy storage system or uninterruptible power supply.

3. The power battery health prediction and evaluation system according to claim 2, wherein the database unit comprises:
a memory which is arranged to store at least:
electrical characteristics of batteries of different brands including charging, discharging and impedance-associated data;
battery internal-resistance, battery voltage and battery current of the battery under test; and
an AI model established by the AI processing unit; and
a measurement interface connected with the memory, which is programmed with LabVIEW, equipped with a data acquisition system (DAQ), and connected with an external circuit to measure the battery voltage and further calculate the internal-resistance of the battery according to a measured voltage difference of the battery, and stores the tested associated data into the memory.

4. The power battery health prediction and evaluation system according to claim 2, wherein the LAN controller transmits the state data of the battery under test to the AI processing unit using CAN bus standard to achieve bidirectional data transmission.

5. The power battery health prediction and evaluation system according to claim 4, wherein after being connected with the battery under test, the measuring interface is arranged to measure the battery internal-resistance, battery voltage and battery current to obtain various associated parameters, and analyze power motor state, vehicle speed and running state of the electric vehicle to obtain parameters thereof.

6. The power battery health prediction and evaluation system according to claim 5, wherein the measurement interface measures the battery internal-resistance, battery voltage and battery current to obtain the various associated parameters, and the measured voltage value of the battery under test is taken as a first reference voltage; when load resistance is switched to 10 ohms after several seconds, the voltage value of the battery under test is taken as a second reference voltage; the first reference voltage is subtracted by the second reference voltage to obtain a voltage difference value; the second reference value is divided by the load resistance to obtain a batter current value; and the voltage difference is divided by the batter current value to obtain the battery internal-resistance value.

7. The power battery health prediction and evaluation system according to claim 2, wherein the deep learning, induction, summarization and repetition training of the AI processing unit adopts recurrent neural network (RNN), long-term and short-term memory model (LSTM) or gated cycle unit (GRU).

8. The power battery health prediction and evaluation system according to claim 2, wherein the AI processing unit predicts a health level of the battery under test by performing forward propagation the obtained historical data and substantive data one by one, introducing an obtained output result and a standard answer into a loss formula to calculate the difference between the two, and then using a gradient descent-like optimizer to perform backward propagation to adjust a weighting in each perception, to train a model under an objective of reducing the difference, so as to provide precise accurate battery life prediction and health assessment.

9. A charger comprising the power battery health prediction and evaluation system for an electric vehicle, energy storage system and uninterruptible power supply according to claim 2, wherein a protocol signal trace in the system further provides a communication protocol for three-way connection between the charger, the system and the power battery of the electric vehicle; when the electric vehicle is being charged, the protocol signal trace is connected with the on-board diagnosis system (OBD II) on the electric vehicle to synchronously read various electrical characteristics of the power battery of the electric vehicle.

10. The charger according to claim 9, further comprising a DC power trace and an AC power trace respectively connectable to a DC charger or an AC charger to provide required amount of charging power.

11. An energy storage system comprising the power battery health prediction and evaluation system for an electric vehicle, energy storage system and uninterruptible power supply according to claim 2, wherein a protocol signal trace in the system is connected with a battery of the energy storage system to provide a protocol for mutual communication.

12. An uninterruptible power supply comprising the power battery health prediction and evaluation system for an electric vehicle, energy storage system and uninterruptible power supply according to claim 2, wherein a protocol signal trace in the system is connected with a battery of the energy storage system to provide a protocol for mutual communication.
